(19) United States
(12) Patent Application Publication
(10) Pub. No.: US 2012/0141929 A1
(43) Pub. Date: Jun. 7, 2012

(54) METHOD FOR MANUFACTURING HALF-TONE MASK, AND HALF-TONE MASK

(75) Inventor: Ryo Yamakawa, Osaka (JP)

(73) Assignee: SHARP KABUSHIKI KAISHA, Osaka (JP)

(21) Appl. No.: 13/390,387

(22) PCT Filed: Aug. 5, 2010
(86) PCT No.: PCT/JP2010/063270

§ 371 Date: Feb. 14, 2012

(30) Foreign Application Priority Data
Sep. 1, 2009 (JP) 2009-201176

(51) Int. Cl. G03F 1/32

(52) U.S. Cl. 430/5

(57) ABSTRACT

Provided is a method of manufacturing a half-tone mask that can reduce the number of film forming steps. The method according to the present invention is for manufacturing a half-tone mask to be interposed between a light source and a photosensitive layer so as to form plural kinds of exposure patterns that have different exposure levels on the photosensitive layer, the half-tone mask including a transparent substrate 2 that has, on a surface thereof, a transmissive section 21 that transmits light radiated from a light source, a light-shielding section 34 that is made of a light-shielding film 7 that blocks light, and that is formed on the surface of the transparent substrate 2, and a semi-light-shielding section 33 that is made of a semi-light-shielding film 3 that transmits a reduced amount of the light, and that is formed on the surface of the transparent substrate 2. The method includes a step of forming a semi-light-shielding film 3 on the surface of the transparent substrate 2, and a step of forming a light-shielding section 34 on the surface of the transparent substrate 2 by radiating laser light 6 from another light source to the semi-light-shielding film 3 under an ozone atmosphere so as to cause a chemical reaction that changes the irradiated portion of the semi-light-shielding film 3 to the light-shielding film 7.

### TECHNICAL FIELD

The present invention relates to a method of manufacturing a half-tone mask, and a half-tone mask.

### BACKGROUND ART

A process of manufacturing a flat panel display and the like employs photolithography in which a photoresist that is made of a photosensitive resin or the like is exposed to light through a photomask so as to transfer a pattern from the photomask to the photoresist. The photomask used in this technique generally includes a transmissive section (transparent section) that transmits light, and a light-shielding section that blocks light. A pattern corresponding to a shape of the transmissive section is formed on the photoresist. A pattern corresponding to a shape of the light-shielding section is formed on the photoresist as a non-exposure pattern.

In photolithography, a technique employing a photomask that also includes a semi-transmissive section (semi-light-shielding section) in addition to the transmissive section and the light-shielding section has been drawing particular attention in recent years. The light-transmittance of the semi-transmissive section is intermediate between the light-transmittance of the transmissive section and that of the light-shielding section. This photomask is generally called a half-tone mask or the like, and has an advantage in that it makes it possible to form a plurality of patterns having different exposure levels on the photoresist with a single exposure. By using this half-tone mask, the number of photomasks to be used and the number of manufacturing process steps can be reduced, which leads to a reduction in manufacturing costs.

As described in Patent Document 1, for example, a conventional half-tone mask is constituted of a transparent substrate made of quartz or the like, a semi-transparent film (hereinafter semi-light-shielding film) that is made of molybdenum silicide or the like and that is formed on a surface of the transparent substrate, and a light-shielding film that is made of chrome or the like and that is laminated on the semi-light-shielding film. This half-tone mask has a transmissive section, which is a portion of the surface of the transparent substrate exposed from the semi-light-shielding film, a semi-light-shielding section that is constituted of a portion of the semi-light-shielding film not covered by the light-shielding film, and a light-shielding section that is constituted of the light-shielding film.

As described in Patent Document 1 and the like, generally, in the conventional method of manufacturing a half-tone mask, a semi-light-shielding film is first formed on the entire surface of the transparent substrate by sputtering or the like. Thereafter, sputtering or the like is performed to further form a light-shielding film on the entire semi-light-shielding film that has been formed. That is, in order to obtain a semi-light-shielding section and a light-shielding section, the conventional method of manufacturing a half-tone mask required at least two sputtering processes or the like to form, on the transparent substrate, a laminated body constituted of films (a semi-light-shielding film and a light-shielding film) that respectively become the above-mentioned sections.

After the laminated body is formed, an electron beam resist (photoresist) layer is formed thereon. Thereafter, exposure is performed for the electron beam resist layer by radiating electron beam to the electron beam resist layer so as to transcribe a pattern to the electron beam resist layer. The electron beam resist layer having the transcribed pattern is then developed, and the electron beam resist layer after the development is used as a mask (protective film) in performing etching or the like of the laminated body on the transparent substrate. A half-tone mask is obtained in this manner.

### RELATED ART DOCUMENTS

### Patent Documents

Patent Document 1: Japanese Patent Application Laid-Open Publication No. 2000-75466

### SUMMARY OF THE INVENTION

### Problems to be Solved by the Invention

In the conventional method of manufacturing a half-tone mask, as described in Patent Document 1 and the like, it was necessary to form a semi-light-shielding film and a light-shielding film, which respectively become a semi-light-shielding section and a light-shielding section, separately on a transparent substrate by sputtering or the like. The film forming process such as sputtering is an expensive process due to a very high cost of equipment and the like, and therefore has been causing a cost of the half-tone mask to increase. For this reason, the reduction in the number of film forming steps has been demanded in the method of manufacturing a half-tone mask.

It is an object of the method of manufacturing a half-tone mask according to the present invention to reduce the number of film forming steps by obtaining not only a semi-light-shielding section, but also a light-shielding section from a semi-light-shielding film formed on a transparent substrate.

### Means for Solving the Problems

A method of manufacturing a half-tone mask according to the present invention is as follows.

(1) A method of manufacturing a half-tone mask to be interposed between a light source and a photosensitive layer to form plural kinds of exposure patterns having different exposure levels on the photosensitive layer, the half-tone mask including: a transparent substrate having, on a surface thereof, a transmissive section that transmits light radiated from a light source; a light-shielding section that is made of a light-shielding film that blocks the light, and that is formed on the surface of the transparent substrate; and a semi-light-shielding section that is made of a semi-light-shielding film that transmits a reduced amount of the light, and that is formed on the surface of the transparent substrate, the method including:

forming the semi-light-shielding film on the surface of the transparent substrate; and

forming the light-shielding section on the surface of the transparent substrate by radiating laser light from another light source to the semi-light shielding film under an ozone atmosphere so as to cause a chemical reaction by which an irradiated portion of the semi-light-shielding film is changed to the light-shielding film.

(2) The method of manufacturing a half-tone mask described in (1) above, wherein, in the step of forming the semi-light-shielding film, a semi-light-shielding film is formed on the surface of the transparent substrate so as to correspond to the light-shielding section and the semi-light-shielding section, respectively.

(3) The method of manufacturing a half-tone mask described in (1) or (2) above, wherein the semi-light-shielding film includes Cr2O3, and the light-shielding film includes CrO2.

A half-tone mask according to the present invention is as follows.

(4) A half-tone mask to be interposed between a light source and a photosensitive layer so as to form plural kinds of exposure patterns that have different exposure levels are formed on the photosensitive layer, the half-tone mask including:

a transparent substrate having, on a surface thereof, a transmissive section that transmits light radiated from a light source;

a light-shielding section that is made of a light-shielding film that blocks the light, and that is formed on the surface of the transparent substrate; and

a semi-light-shielding section that is made of a semi-light-shielding film that transmits a reduced amount of the light, and that is formed on the surface of the transparent substrate,

wherein the light-shielding film is formed from the semi-light-shielding film through a chemical reaction.

(5) The half-tone mask according to (4) above, wherein the light-shielding film is formed from the semi-light-shielding film through the chemical reaction that is caused by laser light irradiation performed under an ozone atmosphere.

(6) The half-tone mask according (4) or (5) above, wherein the semi-light-shielding film includes Cr2O3, and the light-shielding film includes CrO2.

### Effects of the Invention

According to the method of manufacturing a half-tone mask of the present invention, by utilizing a semi-light-shielding film formed on a transparent substrate to obtain not only a semi-light-shielding section, but also a light-shielding section as well, the number of film forming steps can be reduced.

### BRIEF DESCRIPTION OF THE DRAWINGS

FIG. 1 is an explanatory diagram schematically showing a method of manufacturing a half-tone mask according to one embodiment.

FIG. 2 is an explanatory diagram schematically showing a method of manufacturing a half-tone mask according to another embodiment.

FIG. 3 is an explanatory diagram schematically showing a process of exposure for a photosensitive layer using a half-tone mask.

### DETAILED DESCRIPTION OF EMBODIMENTS

A method of manufacturing a half-tone mask according to one embodiment of the present invention will be explained below with reference to a figure.

### Method of Manufacturing Half-Tone Mask

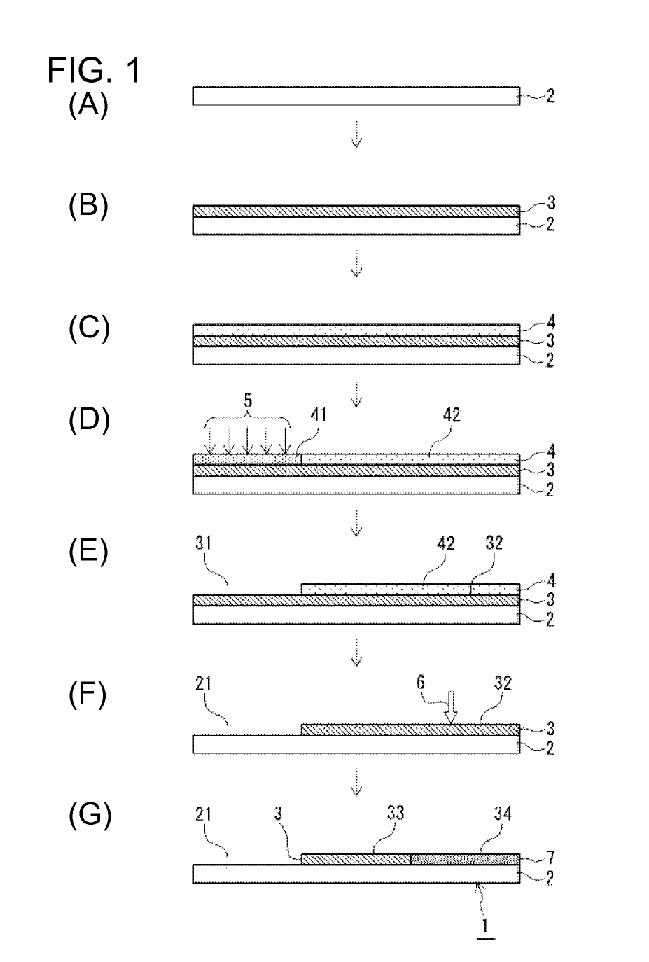

FIG. 1 is an explanatory diagram schematically showing a method of manufacturing a half-tone mask according to one embodiment. First, as shown in FIG. 1(A), a transparent substrate 2 is prepared. This transparent substrate 2 is made of quartz, and has an excellent light transmittance. In other embodiments, a substrate made of other transparent materials such as glass may be used. Conditions of the transparent substrate 2, such as the thickness, the light transmittance, and the shape, can be suitably selected as needed.

Step of Forming Semi-Light-Shielding Film

Next, as shown in FIG. 1(B), on one surface of the transparent substrate 2, a film 3 made of Cr2O3 (hereinafter Cr2O3 film) is formed. This Cr2O3 film 3 is formed by sputtering (reactive sputtering). In the sputtering, Cr is used as a target, and the transparent substrate 2 is placed to have a prescribed distance from the target. By applying a voltage between the target and the transparent substrate 2 under an O2 gas and Ar gas atmosphere, a chromium oxide film (Cr2O3 film) 3 is formed on the surface of the transparent substrate 2. When the sputtering is performed with the distance between the target (Cr) and the transparent substrate 2 set to 100 mm, the applied voltage set to 40 kW, and the vacuum level set to 10-6 torr (5×10-3 torr during the sputtering), for example, the Cr2O3 film 3 of 920 Å can be formed on the surface of the transparent substrate 2. The conditions of the sputtering can be suitably selected as needed.

The Cr2O3 film 3 is a semi-light-shielding film, and has a property of absorbing and therefore blocking part of radiated light. That is, the semi-light-shielding film 3 transmits a reduced amount of radiated light. In the present specification, the definition of “semi-light-shielding” is not limited to shielding exactly half of the radiated light. It can also mean shielding more than half or less than half of the light. The light absorptance of this semi-light-shielding film 3 is lower than that of a light-shielding film, which will be later described. That is, the light transmittance of the semi-light-shielding film 3 is higher than that of the light-shielding film. The light absorptance (or the light transmittance) of the semi-light-shielding film 3 can be determined by suitably selecting various conditions such as the material, the film thickness, and the density.

In other embodiments, the semi-light-shielding film 3 may be formed on the surface of the transparent substrate 2 by using other film forming methods known in the art such as vacuum deposition and chemical deposition.

Next, as shown in FIG. 1(C), on the surface of the semi-light-shielding film 3, a layer 4 made of an electron beam resist (EB resist) (hereinafter EB resist layer) is formed. This EB resist layer 4 is formed by utilizing the spin-on method to apply the EB resist to the surface of the semi-light-shielding film 3 that is formed on the transparent substrate 2. In this embodiment, the EB resist layer 4 is formed in the thickness of about 450 nm to about 550 nm. The EB resist is of a positive-type, and a portion thereof that has been irradiated with an electron beam is removed when the resist is developed. In other embodiments, a negative-type EB resist may be used. In this case, a portion that has been irradiated with an electron beam remains when the resist is developed. Also, instead of the spin-on method, other coating methods known in the art may be used to form the EB resist layer 4 on the semi-light-shielding film 3.

Next, as shown in FIG. 1(D), an electron beam 5 is radiated to the EB resist layer 4 to transcribe a pattern 41 on the EB resist layer 4. This pattern 41 corresponds to a pattern (transmissive pattern) constituted of a transmissive section that will be formed in a half-tone mask. A pattern 42 made of the remaining portion that has not been irradiated with the electron beam 5 corresponds to patterns that respectively become a semi-light-shielding section and a light-shielding section of a half-tone mask (a semi-light-shielding pattern and a light-shielding pattern). After forming the pattern 41 on the EB resist layer 4, the EB resist layer 4 is soaked in a developer bath, and is thereafter developed.

When the EB resist layer 4 is developed, as shown in FIG. (E), the portion of the EB resist layer 4 that corresponds to the pattern 41 is removed, thereby exposing a portion 31 of the semi-light-shielding film 3. The remaining portion 32 of the semi-light-shielding film 3 is covered by the EB resist layer 4 (pattern 42) that has not been removed in the development.

By using the EB resist layer 4 (pattern 42) obtained in the above-mentioned manner as a mask (protective film), the exposed portion 31 of the semi-light-shielding film 3 is etched by the parallel plate reactive ion etching method (RIE). As the etching gas, O2 is used with the controlled flow rate of 100 sccm, for example. The RF power is set to 150 W (500 W or less), the pressure is set to 10 Pa, the distance between electrodes is set to 60 mm, the discharge frequency is set to 13.56 MHz, and the magnetic field strength is set to 100 G, for example.

When the etching is performed under the above-mentioned conditions, as shown in FIG. 1(F), the portion 31 of the semi-light-shielding film 3 that is not covered by the EB resist layer 4 (pattern 42) is removed, thereby exposing a portion 21 of the transparent substrate 2. On the other hand, the remaining portion 32 of the semi-light-shielding film 3 is protected by the EB resist layer 4 (pattern 42) and therefore remains intact. After etching, the remaining EB resist layer 4 (pattern 42) that covers the portion 32 of the semi-light-shielding film 3 is removed by ashing. The conditions for the ashing are suitably selected so that the EB resist layer 4 (pattern 42) can be removed.

Step of Forming Light-Shielding Section

As shown in FIG. 1(F), the portion 32 of the semi-light-shielding film 3 remains on the transparent substrate 2, and laser light 6 is radiated to a part of the portion 32 that becomes a light-shielding section of the half-tone mask. The laser light 6 is radiated under an 03 (ozone) atmosphere. When the semi-light-shielding film 3 made of the Cr2O3 film is irradiated with the laser light 6 and is heated under the ozone atmosphere, a chemical reaction (oxidation) occurs, and Cr2O3 in the semi-light-shielding film 3 is therefore changed to CrO2 that has a light-shielding property. That is, by radiating the laser light 6 to the semi-light-shielding film 3 under prescribed conditions, the semi-light-shielding film 3 can be changed to a light-shielding film 7, as shown in FIG. 1(G).

As the laser light 6, yttrium aluminium garnet laser (YAG laser) can be used, for example. The YAG laser is used with the laser output of 60 mW, the laser diameter of 20 μm, and the laser wave length of 266 nm, for example. The laser light irradiation is performed under the atmosphere in which the pressure is 10-5 Pa (0.1 Pa during introduction of ozone), for example. By the laser light 6, a part of the semi-light-shielding film 3 is heated to 400° C. to 600° C., for example.

The portion of the semi-light-shielding film 3 that has been changed to the light-shielding film 7 by the irradiation with the laser light 6 becomes a light-shielding section 34 as shown in FIG. 1(G). A portion of the semi-light-shielding film 3 that has not been irradiated with the laser light 6 becomes a semi-light-shielding section 33 as shown in FIG. 1(G). A portion of the surface of the transparent substrate 2 that is exposed from the semi-light-shielding film 3 and the light-shielding film 7 becomes a transmissive section 21. A half-tone mask 1 having the transmissive section 21, the semi-light-shielding section 33, and the light-shielding section 34 is obtained in this manner.

According to the method of manufacturing a half-tone mask of this embodiment, both the semi-light-shielding section 33 and the light-shielding section 34 can be formed from a film (semi-light-shielding film 3) obtained by a single sputtering process (see FIG. 1(B)). Because the manufacturing method of this embodiment allows the light-shielding section 34 to be formed from the semi-light-shielding film 3, there is no need to perform another sputtering to form the light-shielding film 7 separately, unlike in the conventional manufacturing method.

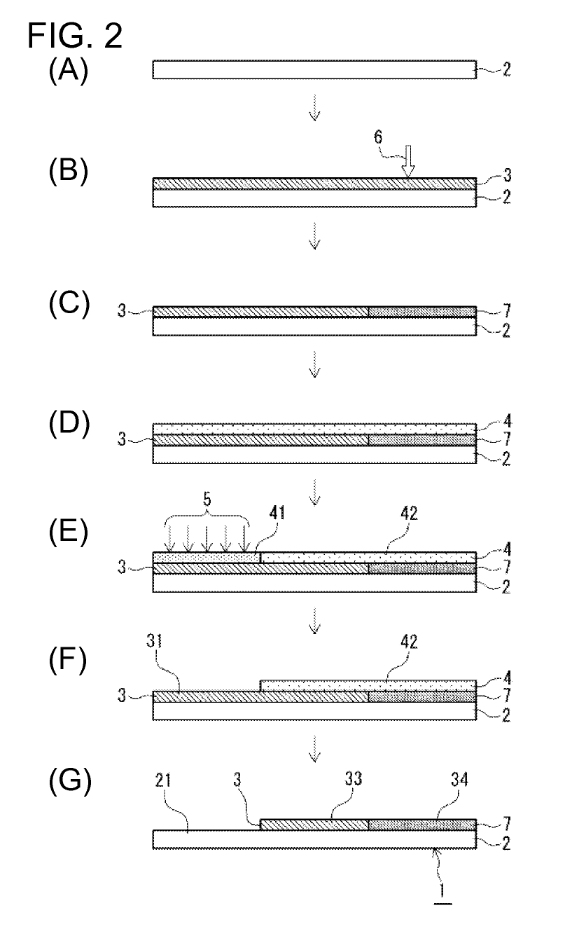

FIG. 2 is an explanatory diagram schematically showing a method of manufacturing a half-tone mask according to another embodiment. The method of manufacturing a half-tone mask according to another embodiment will be explained below with reference to FIG. 2. First, as shown in FIG. 2(A), a transparent substrate 2 is prepared, and thereafter, as shown in FIG. 2(B), a semi-light-shielding film 3 is formed on the surface of the transparent substrate 2. That is, this method is the same as the method shown in FIG. 1 up to the point where the semi-light-shielding film 3 is formed on the surface of the transparent substrate 2.

Next, as shown in FIG. 2(B), in the method of manufacturing a half-tone mask of this embodiment, laser light 6 is radiated to the semi-light-shielding film 3. The laser light 6 is radiated so as to cause a chemical reaction to change a portion of the semi-light-shielding film 3 to a light-shielding film 7 as shown in FIG. 2(C). That is, in this embodiment, the semi-light-shielding film 3 is irradiated with the laser light 6, and the light-shielding film 7 is therefore obtained before the semi-light-shielding film 3 is etched. The method of radiating the laser light 6 to obtain the light-shielding film 7 from the semi-light-shielding film 3 is the same as the method shown in FIG. 1.

Thereafter, as shown in FIG. 2(D), an EB resist layer 4 is formed on the surfaces of the semi-light-shielding film 3 and the light-shielding film 7. Next, as shown in FIG. 2(E), an electron beam 5 is radiated to a portion of the EB resist layer 4 so as to transcribe a pattern 41 on the EB resist layer 4. Next, as shown in FIG. 2(F), the EB resist layer 4 is developed to remove a portion of the EB resist layer 4 where the pattern 41 is transcribed. A portion 31 of the semi-light-shielding film 3 is therefore exposed. Thereafter, by using the remaining portion 42 of the EB resist layer 4 as a mask (protective film), the semi-light-shielding film 3 is etched. By the etching, the portion 31 of the semi-light-shielding film 3 that is not covered by the EB resist layer 4 (42) is removed, and a portion 21 of the surface of the transparent substrate 2 is therefore exposed as shown in FIG. 2(G). After the etching, the remaining EB resist layer 4 (42) is removed by ashing. A half-tone mask 1 shown in FIG. 2(G) having the transmissive section 21, the semi-light-shielding section 33, and the light-shielding section 34 may be manufactured in the above-described manner.

Half-Tone Mask

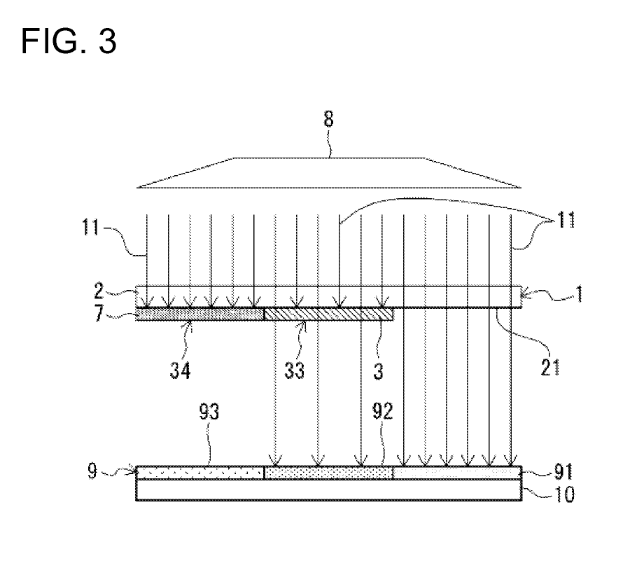

A half-tone mask according to one embodiment will be explained below with reference to FIG. 3. FIG. 3 is an explanatory diagram schematically showing an exposure process of a photosensitive layer in which the half-tone mask 1 is used. As shown in FIG. 3, the half-tone mask 1 is interposed between a light source 8 and a photosensitive layer 9 made of a photosensitive material such as a photosensitive resin. The photosensitive layer 9 is formed on a surface of a substrate 10 to be processed. The half-tone mask 1 is placed substantially parallel to the photosensitive layer 9, and transmits an adjusted amount of light radiated from the light source 8. The half-tone mask 1 has, on one surface thereof, the transmissive section 21 constituted of an exposed portion of the surface of the transparent substrate 2, the semi-light-shielding section 33 constituted of the semi-light-shielding film 3, and the light-shielding section 34 constituted of the light-shielding film 7. In this embodiment, the half-tone mask 1 is placed so that the semi-light-shielding film 3 and the light-shielding film 7 face the photosensitive layer 9.

The transmissive section 21 directly transmits light 11 radiated from the light source 8. After passing through the transmissive section 21, the light 11 reaches a portion of the photosensitive layer 9 located directly below the transmissive section 21, and therefore, that portion of photosensitive layer 9 is exposed to the light. This causes the pattern of the transmissive section 21 (transmissive pattern) to be transferred to the photosensitive layer 9, and an exposure pattern 91 is therefore formed on the photosensitive layer 9.

The semi-light-shielding section 33 absorbs and blocks part of the light 11 radiated from the light source 8. That is, the semi-light-shielding section 33 transmits a reduced amount of the light 11 radiated from the light source 8. After passing through the semi-light-shielding section 33, the light 11 reaches a portion of the photosensitive layer 9 that is located directly below the semi-light-shielding section 33, and therefore, that portion of the photosensitive layer 9 is exposed to the light. This causes a pattern of the semi-light-shielding section 33 (semi-light-shielding pattern) to be transferred to the photosensitive layer 9, and an exposure pattern 92 is therefore formed on the photosensitive layer 9.

The light-shielding section 34 absorbs and blocks the light 11 radiated from the light source 8. Therefore, the light-shielding section 34 does not transmit the light 11 radiated from the light source 8. That is, a portion of the photosensitive layer 9 that is located directly below the light-shielding section 34 is not exposed to the light 11 radiated from the light source 8. This causes a pattern of the light-shielding section 34 (light-shielding pattern) to be transferred to the portion of the photosensitive layer 9 covered by the light-shielding section 34, and a non-exposure pattern 93 is therefore formed.

As described above, by radiating the light 11 from the light source 8 to the photosensitive layer 9 through the half-tone mask 1, respective patterns 91, 92, and 93 that have different exposure levels can be formed in the photosensitive layer 9. When the photosensitive layer 9 is a positive type, the pattern 91 in the photosensitive layer 9 that has the highest exposure level is removed by the development. The pattern 93 in the photosensitive layer 9 that has the lowest exposure level (exposed to no light) remains intact after the development. The exposure level of the pattern 92 in the photosensitive layer 9 is between the exposure level of the pattern 93 and the exposure level of the pattern 91, and therefore, the thickness of the photosensitive layer 9 with the pattern 93 is reduced by about half after the development.

The method of manufacturing a half-tone mask, and the half-tone mask have been explained above. However, the present invention is not limited to such. Although the half-tone mask that three tones including the transmissive section, the semi-light-shielding section, and the light-shielding section has been described in the respective embodiments above, the present invention is not limited to the half-tone mask with the three tones, and the present invention encompasses a half-tone mask that has two or more semi-light-shielding sections that have different levels of light transmittance (light absorptance) in addition to the transmissive section and the light-shielding section (so-called multi-tone mask), for example. In this case, respective semi-light-shielding sections can be obtained by suitably selecting the conditions of laser light irradiation and the like so as to adjust the extent of the chemical reaction that changes a semi-light-transmissive film to a light-shielding film.

1: A method of manufacturing a half-tone mask to be interposed between an exposure light source and a photosensitive layer to form plural kinds of exposure patterns having different exposure levels on the photosensitive layer, the half-tone mask including: a transparent substrate having, on a surface thereof, a transmissive section that transmits light radiated from the light source; a light-shielding section that is made of a light-shielding film that blocks the light, and that is formed on the surface of the transparent substrate; and a semi-light-shielding section that is made of a semi-light-shielding film that transmits a reduced amount of the light, and that is formed on the surface of the transparent substrate, the method comprising:
forming the semi-light-shielding film on the surface of the transparent substrate; and
forming the light-shielding section on the surface of the transparent substrate by radiating laser light from a light source different from the exposure light source to the semi-light shielding film under an ozone atmosphere so as to cause a chemical reaction by which an irradiated portion of the semi-light-shielding film is changed to the light-shielding film.

2: The method of manufacturing a half-tone mask according to claim 1, wherein, in the step of forming the semi-light-shielding film, the semi-light-shielding film is formed on the surface of the transparent substrate so as to correspond to the light-shielding section and the semi-light-shielding section, respectively.

3: The method of manufacturing a half-tone mask according to claim 1, wherein the semi-light-shielding film includes Cr₂O₃, and the light-shielding film includes CrO₂.

4: A half-tone mask to be interposed between a light source and a photosensitive layer so as to form plural kinds of exposure patterns that have different exposure levels on the photosensitive layer, the half-tone mask comprising:
a transparent substrate having, on a surface thereof, a transmissive section that transmits light emitted from a light source;
a light-shielding section that is made of a light-shielding film that blocks the light, and that is formed on the surface of the transparent substrate; and
a semi-light-shielding section that is made of a semi-light-shielding film that transmits a reduced amount of the light, and that is formed on the surface of the transparent substrate,
wherein the light-shielding film is formed from the semi-light-shielding film by a chemical reaction.

5: The half-tone mask according to claim 4, wherein the light-shielding film is formed from the semi-light-shielding film by the chemical reaction caused by laser light irradiation under an ozone atmosphere.

6. The half-tone mask according claim 4, wherein the semi-light-shielding film includes Cr₂O₃, and the light-shielding film includes CrO₂.
